(19) United States
(12) Patent Application Publication
(10) Pub. No.: US 2025/0201673 A1
(43) Pub. Date: Jun. 19, 2025

(54) SEMICONDUCTOR DEVICE AND METHOD OF MANUFACTURING THE SAME

(71) Applicant: Renesas Electronics Corporation, Tokyo (JP)

(72) Inventor: Kazuki MATSUMURA, Tokyo (JP)

(21) Appl. No.: 18/926,505

(22) Filed: Oct. 25, 2024

(30) Foreign Application Priority Data
Dec. 15, 2023 (JP) 2023-212400

(51) Int. Cl. H01L 23/495; H01L 23/00; H01L 23/31

(52) U.S. Cl. CPC H01L 23/49513; H01L 23/3121; H01L 23/49555; H01L 24/43; H01L 24/45; H01L 24/48; H01L 24/32; H01L 24/73; H01L 2224/32245; H01L 2224/4351; H01L 2224/4381; H01L 2224/45147; H01L 2224/45347; H01L 2224/48245; H01L 2224/73265; H01L 2924/13055; H01L 2924/13091

(57) ABSTRACT

A semiconductor device includes: a semiconductor chip having a source electrode pad and mounted on a die pad via a die bonding material; a wire electrically connected with the source electrode pad of the semiconductor chip; and a sealing body sealing the semiconductor chip and the wire. The wire and the source electrode pad are made of different types of metals to each other. A wire bonding layer made of sintered metal is interposed between the source electrode pad and the wire. The wire is electrically connected with the source electrode pad via the wire bonding layer.

### CROSS-REFERENCE TO RELATED APPLICATIONS

The disclosure of Japanese Patent Application No. 2023-212400 filed on Dec. 15, 2023, including the specification, drawings and abstract is incorporated herein by reference in its entirety.

### BACKGROUND

The present embodiments relate to a semiconductor device and a method of manufacturing the same.

There are disclosed techniques listed below.

### [Patent Document 1] Japanese Unexamined Patent Application Publication No. 2002-151554

There is a semiconductor device where a semiconductor chip is mounted on a die pad, and the source electrode of the semiconductor chip and the lead are electrically connected via a metal plate made of conductive resin and copper. For example, in case of the semiconductor device disclosed in Patent Document 1, the source electrode of the semiconductor chip and the source lead are electrically connected via conductive paste and a copper plate. Furthermore, the gate electrode of the semiconductor chip and the gate lead are electrically connected via a bonding wire.

### SUMMARY

In case of a semiconductor device where an electrode pad of a semiconductor chip and a lead are electrically connected with each other via a wire, it is necessary to improve the bonding reliability of a portion where the wire and the electrode pad are electrically connected to each other. For example, when the electrode pad and the wire are made of different types of metals to each other, the bonding strength may decrease compared to a case when the electrode pad and the wire are made of the same types of metals to each other.

Other objects and novel features will become apparent from the description of this specification and the accompanying drawings.

A semiconductor device according to one embodiment includes: a die pad; a lead spaced apart from the die pad; a semiconductor chip having a first electrode pad and mounted on the die pad via a die bonding material; a wire electrically connected with each of the lead and the first electrode pad of the semiconductor chip; and a sealing body sealing the semiconductor chip, the die bonding material and the wire. The first electrode pad and the wire are made of different types of metals to each other. A wire bonding layer made of sintered metal is interposed between the first electrode pad and the wire. The wire is electrically connected with the first electrode pad via the wire bonding layer.

A method of manufacturing a semiconductor device according to another embodiment, includes steps of: (a) preparing a die pad; (b) applying a first paste material onto the die pad; (c) mounting a semiconductor chip having a first electrode pad on the first paste material; (d) arranging a second paste material containing multiple metal particles on the first electrode pad of the semiconductor chip; (e) by heating the second paste material, sintering the multiple metal particles contained in the second paste material, thereby forming a wire bonding layer; and (f) bonding a wire made of a metal which is a different type from the first electrode pad to the wire bonding layer.

According to the embodiment, it is possible to improve the performance of the semiconductor device.

### BRIEF DESCRIPTION OF THE DRAWINGS

FIG. 1 is an upper surface view of a semiconductor device according to one embodiment.

FIG. 2 is a lower surface view of the semiconductor device shown in FIG. 1.

FIG. 3 is a transparent plan view showing an internal structure of the semiconductor device in which a sealing body shown in FIG. 1 is removed.

FIG. 4 is a cross-sectional view along line A-A in FIG. 3.

FIG. 5 is an explanatory diagram schematically showing an example of a circuit included in the semiconductor device shown in FIG. 1.

FIG. 6 is a main portion cross-sectional view showing an example of a device structure of a field-effect transistor shown in FIG. 5.

FIG. 7 is an enlarged cross-sectional view showing a part of each of a semiconductor chip, a wire bonding layer and a wire shown in FIG. 4.

FIG. 8 is an enlarged cross-sectional view showing a part of each of the semiconductor chip, a die bonding material and a die pad shown in FIG. 4.

FIG. 9 is a flowchart showing an example of a method of manufacturing the semiconductor device shown in FIGS. 1 to 4.

FIG. 10 is an enlarged plan view showing a part of the lead frame prepared in a lead frame preparation step shown in FIG. 9.

FIG. 11 is an enlarged cross-sectional view showing a state in which a paste for die bonding is applied onto the die pad in a die bonding paste application step of FIG. 9.

FIG. 12 is an enlarged cross-sectional view showing a state in which the semiconductor chip is mounted on the paste for die bonding shown in FIG. 11.

FIG. 13 is an enlarged cross-sectional view showing a state in which a paste for sintered metal is applied onto the die pad in a sintered metal paste application step of FIG. 9.

FIG. 14 is an explanatory diagram schematically showing a state in which the lead frame is heated in a vacuum furnace in a sintering step shown in FIG. 9.

FIG. 15 is an enlarged cross-sectional view schematically showing a state in which a load and an ultrasonic wave are applied to the wire through a bonding tool in a wire bonding step shown in FIG. 9.

### DETAILED DESCRIPTION

### Description of Format and Basic Terms and Usage in This Application

In this application, the description of embodiments is divided into multiple sections as necessary for convenience, but unless expressly stated otherwise, these are not independent and separate from each other, regardless of the order of description, and parts of a single example, where one part may be a detailed part of another or a part or all of a modified example. Also, in principle, descriptions of similar parts are omitted. Furthermore, each component in an embodiment is not essential, unless expressly stated otherwise, theoretically limited to that number, and obviously not so from the context.

Similarly, in the description of embodiments and the like, regarding materials, compositions, etc., saying “X consisting of A” does not exclude elements other than A, except when it is clearly indicated that this is not the case and when it is obvious from the context that this is not the case. For example, regarding components, it means “X including A as a main component (principal component).” For instance, mentioning “silicon member” does not limit it to pure silicon but includes members containing SiGe (silicon-germanium) alloy or other multicomponent alloys with silicon as the main component, and other additives. Moreover, mentioning gold plating, Cu layer, nickel plating, unless specifically stated otherwise, includes not only pure substances but also members containing gold, Cu, nickel, etc., as the main components.

Furthermore, when mentioning specific numerical values or quantities, unless expressly stated otherwise, theoretically limited to that number, and obviously not so from the context, it may be greater than or less than that specific numerical value.

In the drawings of the embodiments, the same or similar parts are denoted by the same or similar symbols or reference numbers, and the description will not be repeated in principle.

In the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. Furthermore, hatching or dot patterns may be applied not only in cross-sections but also to indicate non-void areas or to delineate boundaries of regions.

In the embodiments described below, as examples of semiconductor devices, semiconductor devices called power devices or power semiconductor devices, which are incorporated into power control circuits such as power supply circuits, are discussed. The semiconductor devices described below are incorporated into power conversion circuits and function as switching elements.

### <Semiconductor Device>

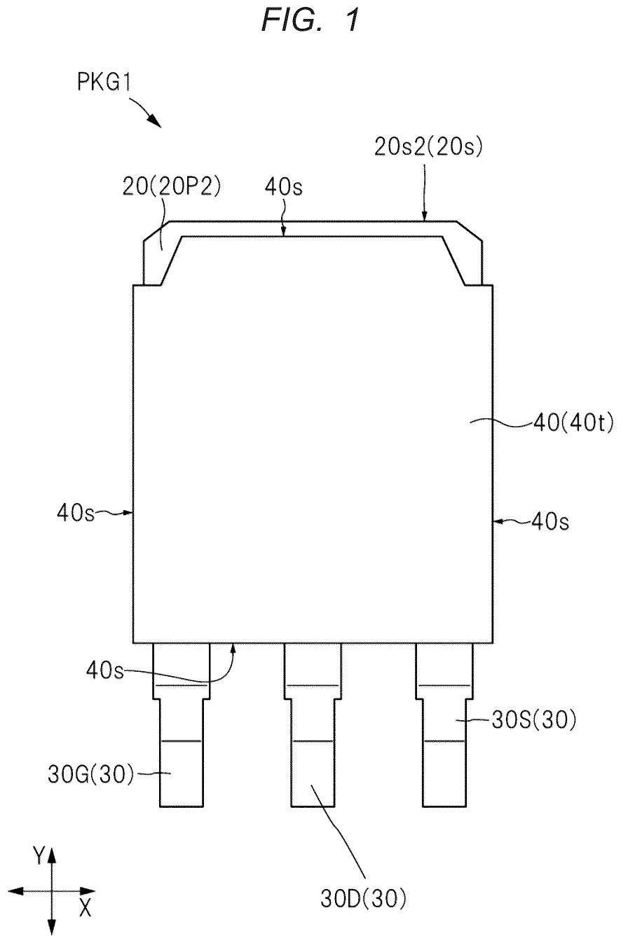

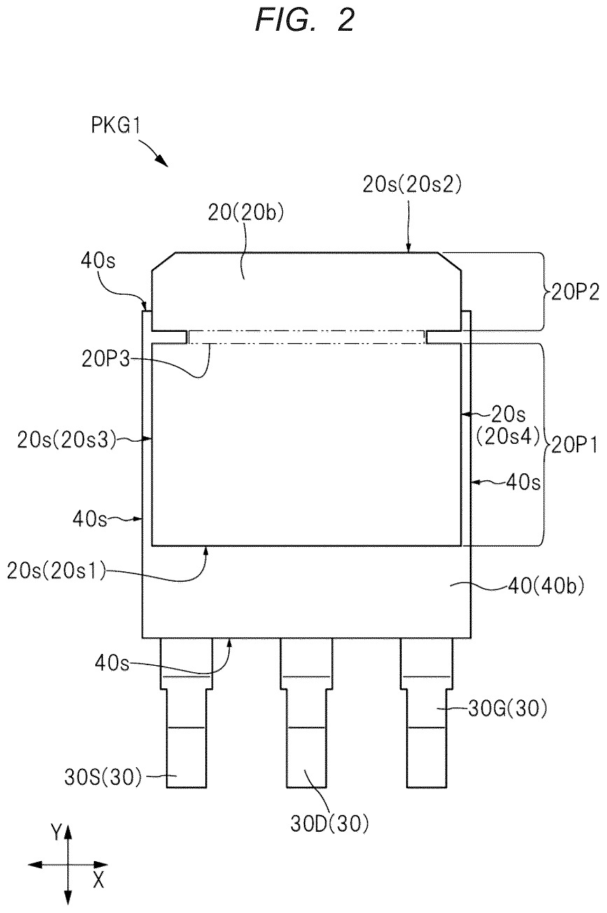

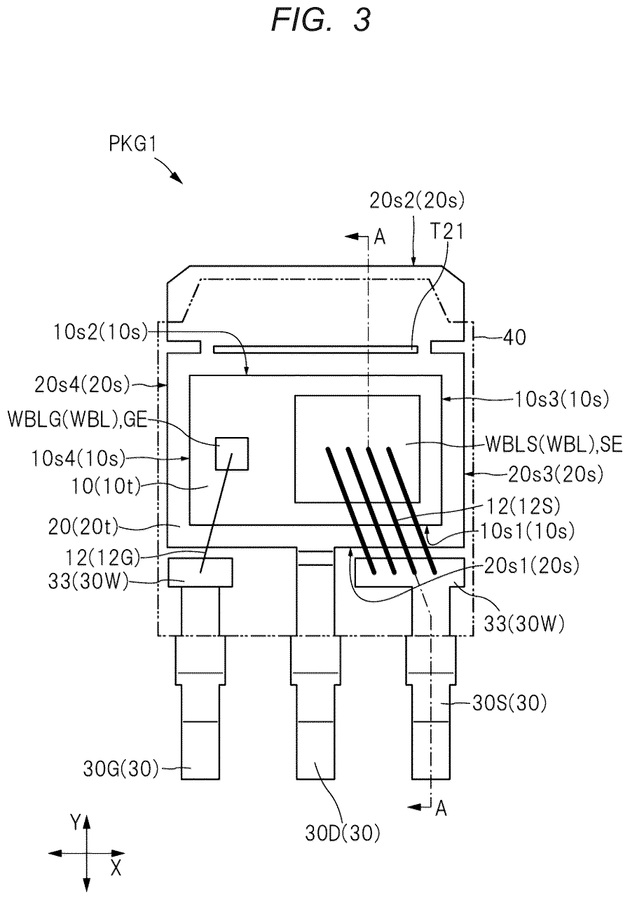

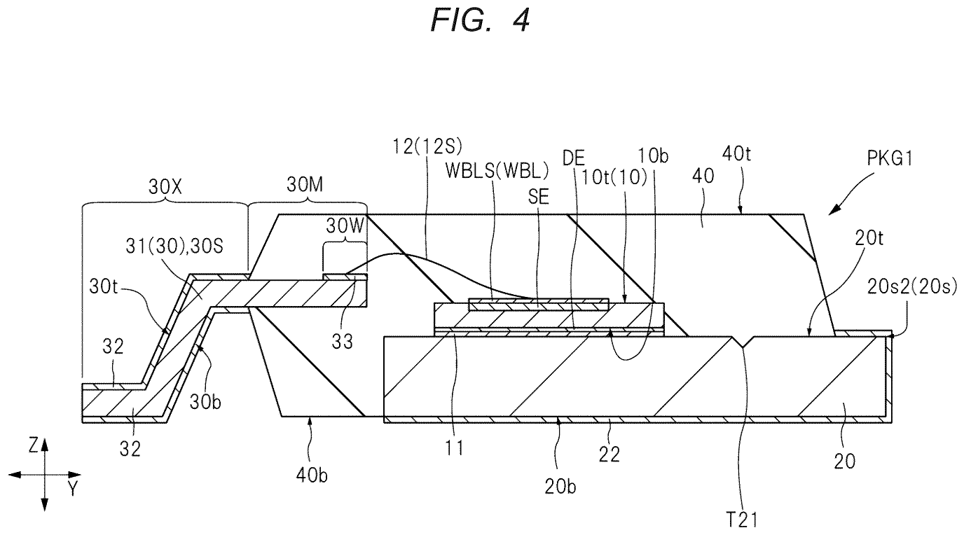

First, the package structure of the semiconductor device PKG1 shown in FIG. 1 is described. FIG. 1 is a top view of the semiconductor device of the present embodiment. Also, FIG. 2 is a bottom view of the semiconductor device shown in FIG. 1. Moreover, FIG. 3 is a perspective plan view showing the internal structure of the semiconductor device with the encapsulation removed, as shown in FIG. 1. Furthermore, FIG. 4 is a cross-sectional view along line A-A in FIG. 3.

FIGS. 1 to 4 describe either the X direction (refer to FIGS. 1 to 3), the Y direction, or the Z direction (refer to FIG. 4). The Y direction is a side intersecting with the X direction, and in the following description, the X direction and the Y direction are orthogonal to each other. The Z direction is orthogonal to both the X direction and the Y direction. In other words, the Z direction is the normal direction to the X-Y plane that includes the X direction and the Y direction. In the following description, “thickness” principally means the length in the Z direction. Also, in the following description, “plan view” principally means the view of the X-Y plane.

The semiconductor device PKG1 of the present embodiment includes a semiconductor chip 10 (refer to FIGS. 3 and 4), a die pad (metal plate, chip mounting part, heat dissipation plate) 20 (refer to FIGS. 2 to 4) on which the semiconductor chip 10 is mounted, a plurality of leads (terminals) 30 which are external terminals, and a plurality of wires 12 (refer to FIG. 3).

As shown in FIG. 3, the die pad 20 has an upper surface (surface) 20t. The semiconductor chip 10 is mounted on the upper surface 20t of the die pad 20 via a die bond material 11 (refer to FIG. 4). The plurality of leads 30 are arranged along a side (chip side) 10s1 of the semiconductor chip 10, which extends in the X direction, among the multiple sides 10s that the semiconductor chip 10 has. The plurality of electrode pads (gate electrode pad GE and source electrode pad SE shown in FIG. 3) arranged on the upper surface (chip surface, surface) 10t of the semiconductor chip 10 and the plurality of leads 30 are electrically connected with each other via a plurality of wires, respectively. As shown in FIG. 4, the semiconductor chip 10 and the plurality of wires 12 are sealed in a sealing body 40. Furthermore, the semiconductor chip 10, the upper surface 20t of the die pad 20, and the inner lead part (sealed part) 30M (refer to FIG. 4) of the plurality of leads 30 are sealed by the sealing body 40. The sealing body (resin sealing body, resin, mold resin) 40 is arranged to contact the die pad 20 and the inner lead part 30M of the leads 30.

As shown in FIG. 4, the semiconductor chip 10 has an upper surface (main surface, front surface, surface) 10t and a lower surface (main surface, back surface, surface) 10b opposite to the upper surface 10t. As shown in FIG. 3, the semiconductor chip 10 has four sides (chip sides) 10s in plain view. The four sides 10s consist of a side 10s1 extending in the X direction, a side 10s2 opposite to side 10s1, a side 10s3 intersecting with sides 10s1 and 10s2 and extending in the Y direction, and a side 10s4 opposite to side 10s3. Side 10s1 is among the four sides 10s of the semiconductor chip 10, positioned closest to each of the plurality of leads 30, and extends in the X direction. In the example shown in FIG. 3, the semiconductor chip 10 forms a rectangle in plain view, with the long sides, sides 10s1 and 10s2, arranged to extend along the X direction.

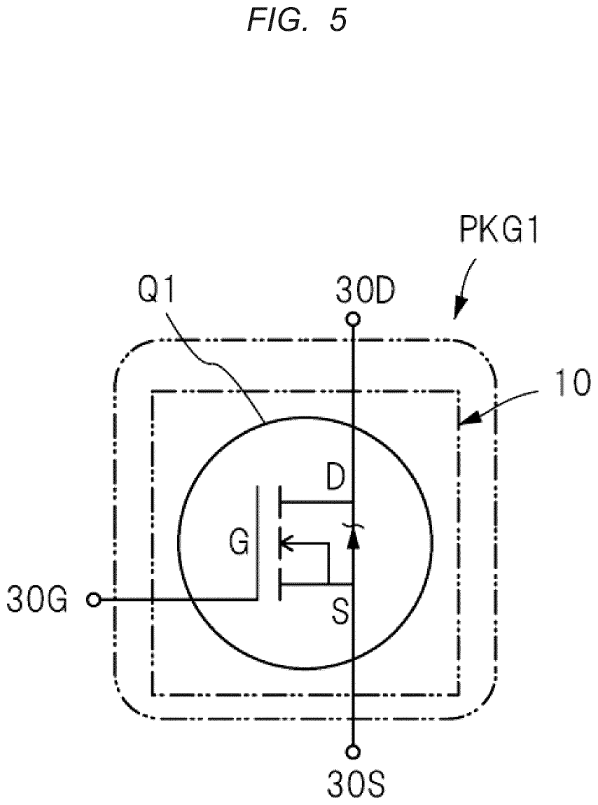

On the upper surface 10t of the semiconductor chip 10, a gate electrode pad GE and a source electrode pad SE are arranged. The insulating film (passivation film) having the upper surface 10t of the semiconductor chip 10 is provided with a plurality of openings. Each of the gate electrode pad GE and the source electrode pad SE is exposed from the insulating film at the openings. The area of the source electrode pad SE is larger than the area of the gate electrode pad GE. The gate electrode pad GE is an electrode pad connected with the gate electrode G of the transistor Q1 shown in FIG. 5 described later. The source electrode pad SE is an electrode pad connected with the source S of the transistor Q1 shown in FIG. 5 described later.

Each of the gate electrode pad GE and the source electrode pad SE is mainly made of aluminum, for example. A metal mainly made of aluminum includes not only aluminum alone but also aluminum alloys to which additive elements such as silicon and copper have been added. When referring to a metal mainly made of aluminum, aluminum constitutes at least 90 percent by weight of the metal, and preferably, 95 percent by weight or more. The elements added to aluminum are not limited to copper and silicon, and various modified examples exist.

As shown in FIG. 4, a drain electrode pad (drain electrode) DE is arranged on the lower surface 10b of the semiconductor chip 10. The drain electrode pad DE is an electrode pad connected with the drain D of the transistor Q1 shown in FIG. 5, which will be described later. In the example shown in FIG. 4, the entire lower surface 10b of the semiconductor chip 10 serves as the drain electrode pad DE.

The drain electrode pad DE is made of a metal film. Although details will be described later, it is preferable that the metal film located at the boundary surface with the die bond material 11 in the metal film composing the drain electrode pad DE is made of a metal that easily bonds with the die bond material 11. For example, in case of the present embodiment, the die bond material 11 is made of sintered copper. Therefore, it is preferable that a metal film made of one of gold, silver, copper and nickel is formed at a portion, which is in contact with the die bond material 11, of the drain electrode pad DE. On the other hand, if the die bond material 11 is solder or a conductive resin (a resin body mixed with multiple conductive particles in a resin including thermosetting resin), it is preferable that a metal film made of one of gold and silver is formed at a portion, which is in contact with the die bond material 11 the metal film composing the drain electrode pad DE.

In the present embodiment, a vertical channel structure MOSFET is exemplified as an example of the transistor Q1. Therefore, the drain electrode pad DE is located on the lower surface 10b of the semiconductor chip 10, which is the opposite side of the surface where the gate electrode pad GE and the source electrode pad SE are arranged. The drain electrode pad DE of the semiconductor chip 10 is electrically connected with the die pad 20 through the die bond material 11.

Although not shown, as a modified example of the present embodiment, when using a lateral channel structure MOSFET, the gate electrode pad GE, the source electrode pad SE, and the drain electrode pad DE are arranged on the upper surface 10t of the semiconductor chip 10.

As shown in FIGS. 3 and 4, the semiconductor device PKG1 has a die pad (metal plate, chip mounting part, heat dissipation plate) 20 on which the semiconductor chip 10 is mounted. Each of the die pad 20 and multiple leads 30 (see FIG. 3) has a substrate 31 made of, for example, copper (Cu) or an alloy material mainly composed of copper (Cu). As shown in FIG. 4, the die pad 20 has an upper surface (surface, main surface, chip mounting surface) 20t on which the semiconductor chip 10 is mounted via the die bond material 11, and a lower surface (surface, main surface, back surface, main surface) 20b opposite to the upper surface 20t.

In the present embodiment, the die bond material 11 consists of a conductive material that electrically connects the drain electrode pad DE (see FIG. 4) and the die pad 20. The die bond material 11 consists of a sintered metal such as sintered copper or sintered silver. In the present embodiment, as shown in FIG. 3, a wire bonding layer WBL made of sintered metal is arranged on the source electrode pad SE. By using sintered metal as the die bond material 11, in the manufacturing process of the semiconductor device, it is possible to sinter both the die bond material 11 and the wire bonding layer WBL in a single sintering treatment.

As a modified example of the die bond material 11, a resin material containing conductive particles or solder can be exemplified. A resin material containing conductive particles is called a conductive resin or conductive paste. Moreover, those using silver particles as conductive particles are called silver paste.

As another modified example, in case of applying a device structure (for example, a transistor with a lateral channel structure) where no electrode is arranged on the lower surface 10b of the semiconductor chip 10, it is not essential for the die bond material 11 to be conductive. In this case, for example, an insulating resin adhesive can be used.

However, as described later, when performing the sintering treatment, a heat treatment at high temperature is performed. Therefore, from the viewpoint of preventing damage to the die bond material 11 during the sintering treatment, it is preferable that the die bond material 11 is a sintered metal.

As shown in FIG. 2, the die pad 20 has four sides 20s in plain view. Specifically, the die pad 20 has a side 20s1 extending in the X direction, a side 20s2 arranged on the opposite side of side 20s1, a side 20s3 extending in the Y direction and intersecting with side 20s1, and a side 20s4 arranged on the opposite side of side 20s3 and intersecting with side 20s1.

The die pad 20 includes a main body part (portion) 20P1 containing the area where the semiconductor chip 10 (see FIG. 3) is mounted, a header part (portion) 20P2 equipped with a side 20s2 arranged on the opposite side of side 20s1 in plain view, and a connecting part (portion) 20P3 connecting the main body part 20P1 and the header part 20P2. Each of sides 20s1, 20s3, and 20s4 is a side of the main body part 20P1 of the die pad 20. Side 20s2 is a side of the header part 20P2 of the die pad 20.

The main body portion 20P1 includes an area for mounting a semiconductor chip 10 (refer to FIG. 3), and an area for contacting a jig to fix the die pad 20 during the process (wire bonding process to be described later) of bonding wires 12 to the semiconductor chip. The main body portion 20P1 forms a quadrangle in plain view. In the example shown in FIG. 2, the main body portion 20P1 forms a rectangle, and the side 20s1 is a long side. The semiconductor chip 10 is arranged in plain view such that the side 10s1 of the semiconductor chip 10 and the side 20s1 of the die pad 20 extend along each other.

The header portion 20P2 is formed integrally with the main body portion 20P1 and the connecting portion 20P3, but the semiconductor chip 10 is not mounted on the header portion 20P2. The side 20s2 of the header portion 20P2 and its periphery are exposed from the sealing body 40. By forming the header portion 20P2, which is exposed from the sealing body 40, and the main body portion 20P1 integrally, the heat dissipation characteristics of the semiconductor device PKG1 can be improved. The connecting portion 20P3 is a part for connecting the header portion 20P2 and the main body portion 20P1.

As shown in FIGS. 2 and 4, the lower surface 20b of the die pad 20 is exposed from the sealing body 40. By exposing the lower surface 20b of the die pad 20 from the sealing body 40, the heat dissipation characteristics of the die pad 20 can be improved. Also, when the die pad 20 is bonded to a terminal of a mounting substrate (not shown), the die pad 20 itself can be used as a drain terminal (or a collector terminal in case of an IGBT).

From the perspective of increasing the thermal capacity of the die pad 20, or from the perspective of increasing the cross-sectional area of the conductive path through which current flows, it is preferable that the thickness (i.e., the length in the Z-direction) of the die pad 20 is thicker. In the example shown in FIG. 4, the thickness of the die pad 20 is larger than the thickness of the semiconductor chip 10. Moreover, the thickness (the distance from the upper surface 20t to the lower surface 20b) of the die pad 20 is larger than the thickness (the distance from the upper surface 30t to the lower surface 30b) of the lead 30. For example, in the example shown in FIG. 4, the thickness of the die pad 20 is about 500 μm to 2000 μm.

Moreover, the part of the die pad 20 that is exposed from the sealing body 40 (the outer part, exposed part) is covered with a metal film 22. Similarly, for each of the multiple leads 30, the part that is exposed from the sealing body 40 (the outer lead part 30X) is covered with a metal film 32. These metal films 22 and 32 are metal films used as a connection material to improve the wettability of the solder material when mounting the semiconductor device PKG1 on a mounting substrate.

As shown in FIGS. 3 and 4, the semiconductor device PKG1 has a plurality of leads 30 that is electrically connected with the semiconductor chip 10. As shown in FIG. 3, each of the multiple leads 30 is facing the side 20s1 of the die pad 20 in plain view. However, as shown in FIG. 4, in the Z-direction, the lower surface 30b of the lead 30 is positioned higher than the upper surface 20t of the die pad 20. Therefore, in the cross-sectional view shown in FIG. 4, the lead 30 is not facing the side 20s1 of the die pad 20. “The multiple leads 30 and the side 20s1 of the die pad 20 facing each other in a plan view” means that, as shown in FIG. 3, the multiple leads 30 and the side 20s1 of the die pad 20 appear to be facing each other in a plan view. Therefore, as shown in FIG. 4, there are cases where the end face of the lead 30 and the end face of the die pad 20 are not facing each other. Although not shown, as a modified example to the present embodiment, cases where the end face of the lead 30 and the end face of the die pad 20 are facing each other are also included in the aforementioned state where “the multiple leads 30 and the side 20s1 of the die pad 20 are facing each other in a plan view.”

A plurality of leads 30 includes a lead for source (source lead, source terminal) 30S, a lead for drain (drain lead, drain terminal) 30D, and a lead for gate (gate lead, gate terminal) 30G. In the example shown in FIG. 3, the plurality of leads 30 are arranged along the X direction. In the example shown in FIG. 3, in the X direction, the leads are arranged in the order of lead 30G, lead 30D, and lead 30S. However, the arrangement order is not limited to the mode shown in FIG. 3, and for example, they may be arranged in the order of lead 30G, lead 30S, and lead 30D.

As shown in FIG. 4, each of the plurality of leads 30 includes an inner lead part 30M that is sealed in the sealing body 40, and an outer lead part (outer part, exposed part) 30X that is exposed from the sealing body 40. In the present embodiment, the outer lead part 30X is bent, and the tip portion of the outer lead part 30X is positioned lower than the inner lead part 30M. The shape of the outer lead part 30X shown in FIG. 4 is called a gull-wing shape.

As shown in FIG. 3, the die pad 20 is integrally formed with the lead 30D, which is a drain terminal. The lead 30D is an external connection terminal that is electrically connected with the drain D shown in FIG. 5, which will be described later. The lead 30D is electrically connected with the drain electrode pad DE of the semiconductor chip 10 (see FIG. 4) through the die pad 20 and the die bond material 11. Also, since the lead 30D is connected with the die pad 20, it has the function of a suspension lead that supports the die pad 20 in the manufacturing process of the semiconductor device to be described later.

Also, as shown in FIG. 3, the gate electrode pad GE of the semiconductor chip 10 and the lead 30G are electrically connected with each other via a wire (conductive member, metal wire) 12 (specifically, a wire for gate 12G). Similarly, the source electrode pad SE of the semiconductor chip 10 and the lead 30S are electrically connected with each other via a wire 12 (specifically, multiple wires for source 12S).

A wire 12 is a conductive member connecting with each of the electrode pad on the upper surface 10t of the semiconductor chip 10 and the lead 30. A material that can be used for the wire 12 includes a metal mainly made of copper (Cu), gold (Au), silver (Ag), or aluminum (Al). In the present embodiment, each of the plurality of wires 12 is a copper wire made of copper. As mentioned above, each of the gate electrode pad GE and the source electrode pad SE is mainly made of aluminum. Therefore, the wire 12 and the source electrode pad SE (or gate electrode pad GE) are made of different types of metals to each other.

Thus, when attempting to directly bond wire 12 and the source electrode pad SE, which are made of different metals, there is room for improvement in terms of electrical connection reliability (for example, bonding strength or electrical characteristics) compared to when bonding metals of the same type.

Therefore, in case of the present embodiment, as shown in FIG. 4, a wire bonding layer WBLS, to which the wire 12S is bonded, is interposed between the source electrode pad SE and the wire 12S. Furthermore, a wire bonding layer WBLG is interposed between the gate electrode pad GE and the wire 12G as shown in FIG. 3. The wire bonding layers WBLS and WBLG are made of the same material and are manufactured by the same manufacturing method. Hereinafter, the wire bonding layer WBLS located on the source electrode pad SE will be described as a representative example, but the term “wire bonding layer WBL” may be used to collectively refer to the wire bonding layers WBLS and WBLG.

The wire bonding layer WBL shown in FIG. 4 is made of sintered metal. In case of the present embodiment, the wire bonding layer WBL is made of sintered copper, which consists of multiple copper particles sintered together. As a modified example of the wire bonding layer WBL, sintered silver, which consists of multiple silver particles sintered together, may also be used. Details of the wire bonding layer WBL made of sintered metal will be described later.

As shown in FIG. 3, one end of the wire 12S for the source is bonded to the wire bonding layer WBLS located on the source electrode pad SE of the semiconductor chip 10. On the other hand, the other end of the wire 12S, opposite to the aforementioned one end, is bonded to a metal film 33 (see FIG. 4) covering the wire bonding area 30W of the lead 30S. One end of the wire 12G for the gate is bonded to the wire bonding layer WBLG located on the gate electrode pad GE of the semiconductor chip 10. Meanwhile, the other end of the wire 12G, opposite to the aforementioned one end, is bonded to a metal film covering the wire bonding area 30W of the lead 30G (illustration omitted). The metal film 33 is, for example, made of nickel (Ni) or silver (Ag). By bonding the wire 12 to the metal film 33 covering the wire bonding area 30W, the bonding strength between the wire 12 and the lead 30 can be improved. The metal film covering the wire bonding area 30W of the lead 30G is made of the same material as the metal film 33 shown in FIG. 4.

Furthermore, in a power semiconductor device, a larger current flow through the wiring path connected with the source electrode pad SE than through the wiring path connected with the gate electrode pad GE. Therefore, in the example shown in FIG. 3, multiple wires 12S are connected with the source electrode pad SE. Also, in the example shown in FIG. 3, each of the multiple wires 12S is thicker than the wire 12G. Moreover, when the wire 12S is made of copper, the electrical conductivity of the wire 12S can be increased compared to when the wire 12S is made of gold or aluminum. Additionally, copper has the advantage of reducing raw material costs compared to silver or gold.

Note that the shape and number of wires 12 are not limited to the embodiment shown in FIG. 3, and various modified examples exist. For instance, in the case where the thickness of wire 12S and wire 12G differs as shown in FIG. 3, even if the raw materials of wire 12S and wire 12G are the same, it is necessary to use different wire bonders. Therefore, for example, wire 12S may be made of copper, while wire 12G may be made of different materials such as gold or aluminum. In this case, the wire bonding layer WBLG located on the gate electrode pad GE may not be placed. Alternatively, in FIG. 3, the thickness of wire 12S is thicker than that of wire 12G, but as a modified example, there may be cases where wires 12 of the same thickness are used. In this case, both wire 12S and wire 12G can be joined by the same wire bonder.

The semiconductor chip 10, the die bond material 11 (refer to FIG. 4), each of the inner lead portions 30M of the plurality of leads 30, the wire bonding layer WBL, and the plurality of wires 12 are sealed by the sealing body 40. The sealing body 40 is a resin body that seals the semiconductor chip 10 and the wires 12. The sealing body 40 has an upper surface 40t (refer to FIGS. 1 and 4) and a lower surface (mounting surface) 40b located on the opposite side of the upper surface 40t (refer to FIGS. 2 and 4). Also, as shown in FIGS. 1 and 2, each of the upper surface 40t (refer to FIG. 1) and the lower surface 40b (refer to FIG. 2) of the sealing body 40 has a plurality of sides 40s at its periphery.

The sealing body 40 is mainly composed of a thermosetting resin such as an epoxy resin, for example. In the present embodiment, to improve the characteristics of the sealing body 40 (for example, expansion characteristics due to thermal effects), filler particles such as silica (silicon dioxide; SiO2) particles are mixed into the resin material, for example.

### <Circuit Configuration Example>

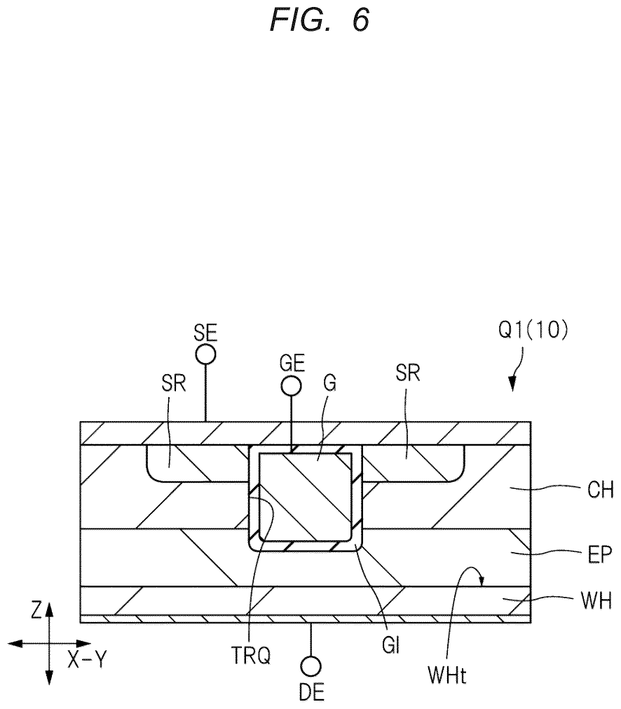

Next, an example of the circuit configuration and the transistor element structure included in the semiconductor device PKG1 shown in FIG. 3 will be described. FIG. 5 is an explanatory diagram schematically showing an example of the circuit included in the semiconductor device shown in FIG. 1. Also, FIG. 6 is a main portion cross-sectional view showing an example of the element structure of the field-effect transistor shown in FIG. 5.

Semiconductor devices for power control, called power semiconductor devices, include semiconductor elements such as diodes, thyristors, or transistors, for example. Transistors are used in various fields, but transistors that are incorporated into power control circuits where a large current of 1 A (Ampere) or more flows and operate as switching elements, as in the present embodiment, are called power transistors. The semiconductor device PKG1 of the present embodiment has a semiconductor chip 10 equipped with a transistor Q1, which is a power transistor, as shown in FIG. 5. In the examples shown in

FIGS. 5 and 6, the transistor Q1 included in the semiconductor chip 10 is a field-effect transistor, specifically, a MOSFET (Metal Oxide Semiconductor Field Effect Transistor). In power semiconductor devices, transistors are used as switching elements, for example. The MOSFET used in power semiconductor devices is called a power MOSFET.

The above-mentioned MOSFET is described as a term broadly representing a field-effect transistor with a structure where a gate electrode made of conductive material is placed on a gate insulating film. Therefore, even when described as a MOSFET, it does not exclude gate insulating films other than oxide films. Also, even when described as a MOSFET, it does not exclude gate electrode materials other than metals, such as polysilicon, for example.

The transistor Q1 shown in FIG. 5 is formed by an n-channel type field-effect transistor, as shown in FIG. 6. FIG. 6 is a main portion cross-sectional view showing an example of the element structure of the field-effect transistor shown in FIG. 5.

In the example shown in FIG. 6, an n-type epitaxial layer EP is formed on the main surface WHt of a semiconductor substrate WH made of, for example, n-type single crystal silicon. The semiconductor substrate WH and the epitaxial layer EP constitute a drain region (a region corresponding to the drain D shown in FIG. 5) of a MOSFET. This drain region is electrically connected with a drain electrode pad DE formed on the lower surface 10b (see FIG. 4) side of the semiconductor chip 10.

On the epitaxial layer EP, a channel formation region CH, which is a p+ type semiconductor region, is formed, and on this channel formation region CH, a source region (a region corresponding to the source S shown in FIG. 5) SR, which is an n+ type semiconductor region, is formed. The source region SR is electrically connected with a source electrode pad SE formed on the upper surface 10t (see FIG. 4) side of the semiconductor chip 10 through a lead wire. Furthermore, in the semiconductor regions stacked on the semiconductor substrate WH, a trench (opening, groove) TRQ is formed, which penetrates the channel formation region CH from the upper surface of the source region SR and reaches inside the epitaxial layer EP.

Moreover, a gate insulating film GI is disposed on the inner wall of the trench TRQ. Furthermore, a gate electrode G, which is stacked so as to fill the trench TRQ, is disposed on the gate insulating film GI. The gate electrode G is electrically connected with a gate electrode pad GE of the semiconductor chip 10 through a lead wire.

Moreover, since the transistor Q1 has the drain region and the source region SR arranged in the thickness direction across the channel formation region CH, a channel is formed in the thickness direction (hereinafter referred to as a vertical channel structure). In this case, compared to a field-effect transistor in which a channel is formed along the main surface WHt, the occupied area of the element in plain view can be reduced. Therefore, the planar size of the semiconductor chip 10 can be reduced.

Moreover, in case of the above-mentioned vertical channel structure, since the channel width per unit area can be increased in plain view, the on-resistance can be reduced. Note that FIG. 6 is a diagram showing the element structure of a field-effect transistor, and in the semiconductor chip 10 shown in FIG. 5, for example, a plurality (a large number) of transistors Q1 having an element structure as shown in FIG. 6 are connected in parallel. This allows for the construction of a power MOSFET through which a large current exceeding, for example, 1 ampere can flow.

As described above, when constructing a MOSFET by connecting multiple transistors Q1 with a vertical channel structure in parallel, the electrical characteristics (mainly voltage resistance characteristics, on-resistance characteristics, and capacitance characteristics) of the MOSFET change according to the planar size of the semiconductor chip 10. For example, if the planar area of the semiconductor chip 10 is increased, the number of cells (i.e., the number of elements) of the transistors Q1 connected in parallel increases, thereby reducing the on-resistance and increasing the capacitance.

It should be noted that, although MOSFETs are exemplified as examples of power transistors provided in the power semiconductor device in FIGS. 5 and 6, various modified examples can be applied. For instance, instead of MOSFET, Insulated Gate Bipolar Transistor (IGBT) may be provided.

Furthermore, in the example shown in FIG. 6, a transistor with a vertical channel structure is exemplarily described, but it can be replaced with a transistor having a horizontal channel structure. In this case, the drain electrode pad DE is arranged on the upper surface 10t (see FIG. 3) of the semiconductor chip 10. Therefore, the drain electrode pad DE (see FIG. 6) connected with the drain of the transistor with a horizontal channel structure and the drain lead 30D shown in FIG. 3 are electrically connected with each other via a wire (drain wire) not shown. In addition, the area of the drain lead 30D where the drain wire is connected (wire bonding area) is covered with a metal film 33, similar to FIG. 4, and the drain wire is connected with the drain lead 30D via the metal film 33.

### <Details of Wire Bonding Layer>

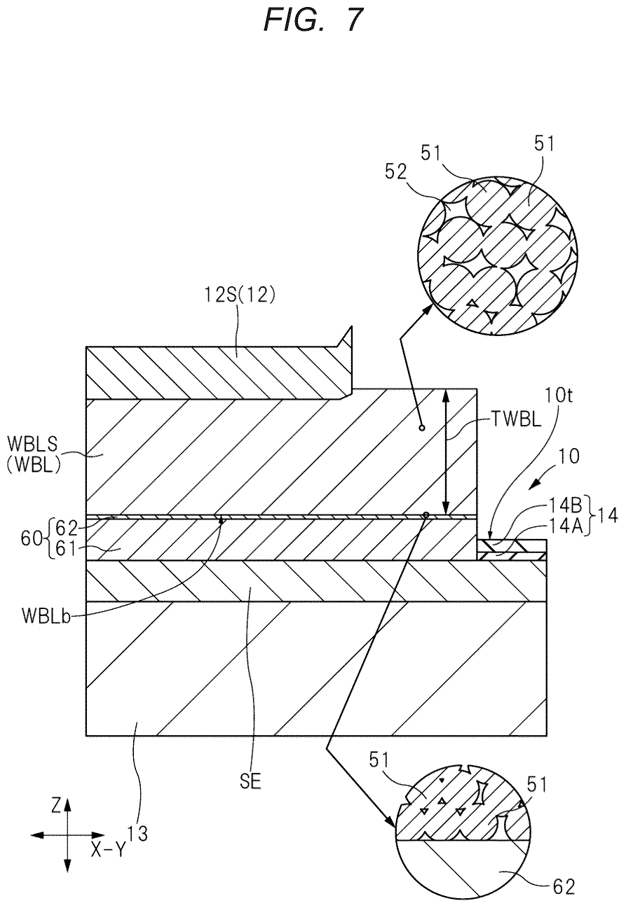

Next, the details of the wire bonding layer WBL shown in FIGS. 3 and 4 will be described. FIG. 7 is an enlarged cross-sectional view showing a part of each of the semiconductor chip, wire bonding layer, and wire shown in FIG. 4. Although not shown in FIG. 7, between the source electrode pad and the semiconductor substrate 13, a wiring layer electrically connected with the transistor Q1 (see FIG. 5) formed on the semiconductor substrate 13 and the source electrode pad SE is formed.

The semiconductor chip 10 has a semiconductor substrate 13, a source electrode pad SE arranged on the semiconductor substrate 13, and an insulating film 14 covering the source electrode pad SE.

In the example shown in FIG. 7, the insulating film 14 is a laminated film of insulating films 14A and 14B. The insulating film 14A is an inorganic insulating film made of, for example, silicon oxide or silicon nitride. On the other hand, the insulating film 14B is an organic insulating film made of, for example, polyimide.

The insulating film 14 is formed to cover the source electrode pad SE, but has an opening formed in part of it. A part of the source electrode pad SE is exposed in the opening from the insulating film 14.

As explained using FIG. 4, when attempting to directly bond the wire 12S, made of a different metal, to the source electrode pad SE, there is room for improvement in terms of electrical connection reliability of the bonding interface compared to when bonding metals of the same kind. For example, in the present embodiment, where the wire 12 is made of copper and the source electrode pad SE is made of aluminum, copper being harder than aluminum, the source electrode pad SE may be damaged by the external force applied during the bonding of the wire 12. When the source electrode pad SE is damaged by the external force, there is a concern that the electrical characteristics of the damaged part of the source electrode pad SE may deteriorate (for example, an increase in resistance value). Furthermore, when the source electrode pad SE is damaged by the external force, there is a concern that the bonding strength between the wire 12 and the source electrode pad SE may decrease.

Therefore, the inventors of the present invention have conducted a study on a method for preventing damage to the source electrode pad SE when bonding wire 12, by placing a layer for bonding wire 12, namely a wire bonding layer WBL, on the source electrode pad SE.

Although not shown, first, a study was conducted on a method of forming a plated metal film on the source electrode pad SE, for example, by plating, and bonding wire 12 to this plated metal film. In case of this examined example, since wire 12 is not directly bonded to the source electrode pad SE, it was found that damage to the source electrode pad SE can be suppressed if the thickness of the plated metal film is sufficiently thick.

However, when forming a metal film by plating, the thicker the metal film is intended to be, the more difficult it becomes to form the film.

In case of the present embodiment, a metal member made of sintered metal is used as the wire bonding layer WBL. As shown in FIG. 7, the wire bonding layer WBL, which is made of sintered metal, is a sintered body in which multiple metal particles 51 are sintered together. Each of the multiple metal particles 51 is a fine particle with a particle size in the submicron order. Moreover, a large number of metal particles 51 can be handled as a powder. Metal particles with a particle size in the nanometer order may also be used. This allows for the sintering of multiple metal particles together at a lower temperature and under a lower load. However, when using metal particles in the nanometer order, there is a risk that the member cost (i.e., the manufacturing cost of the semiconductor device) may become higher compared to using metal particles in the submicron order. Metal particles with a particle size in the micrometer order may also be used. This allows for a reduction in cost. However, when using metal particles in the micrometer order, there is a risk that reactivity (sinterability) may decrease compared to using metal particles in the submicron order.

When forming a sintered body, a binder material is mixed with the powder of metal particles 51 to make a paste material. By shaping this paste material into a predetermined shape and then heating it, multiple metal particles 51 can be sintered together. The binder material evaporates during the heat treatment. The remaining sintered body becomes a porous body with voids 52 between the sintered metal particles 51.

As described above, since sintered metal is shaped from a paste-like raw material, the thickness of the wire bonding layer WBL can be made thicker compared to the method of forming a metal film by plating. For example, in case of the present embodiment, the thickness of the wire bonding layer WBL is about 60 μm. Since the thickness of the source electrode pad SE is about 5 μm, the thickness of the wire bonding layer WBL is more than 10 times the thickness of the source electrode pad SE.

Thus, a wire bonding layer WBL made of sintered metal is easily thickened, making it difficult for external forces applied during the bonding of wire 12 to be transmitted to the source electrode pad SE. Furthermore, the wire bonding layer WBL, being a porous body as described above, allows the external forces applied during the bonding of wire 12 to be mitigated by the voids 52 in the wire bonding layer WBL, making it difficult to transmit to the source electrode pad SE. In the present embodiment, a wire bonding WBL made of sintered metal is provided, and wire 12 is bonded to the wire bonding layer WBL. This prevents or suppresses damage to the source electrode pad SE when bonding wire 12. By suppressing damage to the source electrode pad SE, the electrical connection reliability of the path electrically connecting wire 12 and the source electrode pad SE can be improved.

Each of the plurality of metal particles 51 is, for example, a copper particle. That is, the wire bonding layer WBL is made of sintered copper. As described above, when bonding a wire 12 made of copper, it is particularly preferable for the wire bonding layer WBL to be made of sintered copper.

However, as a modified example, each of the plurality of metal particles 51 may be, for example, a silver particle. In other words, the wire bonding layer WBL may be made of sintered silver. It is possible to bond wire 12 and the wire bonding layer WBL even when the WBL is made of sintered silver. However, copper is a metal with more than twice the hardness (Vickers hardness) compared to silver. Therefore, sintered copper is preferable as the material for the wire bonding layer WBL to which the copper-made wire 12 is bonded.

In case of the present embodiment, as shown in FIG. 7, a metal film 60 is interposed between the wire bonding layer WBL and the source electrode pad SE. A metal film 62 made of one of gold, silver, copper and nickel is formed at a portion, which is in contact with the wire bonding layer WBL, of the metal film 60.

In the example shown in FIG. 7, the metal film 60 is a laminated film consisting of a metal film 61 formed on the source electrode pad SE and a metal film 62 formed on the metal film 61. The metal film 61 is, for example, a nickel film made of nickel. The metal film 62 is, for example, a gold film made of gold. It is preferable for the metal film 60 to be interposed between the wire bonding layer WBL and the source electrode pad SE for the following reasons.

That is, considering the characteristics of the electrical connection path between the source electrode pad SE and wire 12S, it is preferable to reduce the impedance in the electrical connection path between the wire bonding layer WBL made of sintered metal and the source electrode pad SE. In the present embodiment, the wire bonding layer WBL is sintered on the source electrode pad SE, forming a sintered body. At this time, the lower surface WBLb of the wire bonding layer WBL is sintered to the underlying layer (metal film 62 in the example shown in FIG. 7) facing the lower surface WBLb.

When the wire bonding layer WBL is made of sintered copper, the underlying layer is preferably a metal that is easily sintered with copper. This is because sintering the sintered copper over the entire underlying layer can reduce the resistance value at the interface between the sintered copper and the underlying layer. Therefore, it is preferable that the metal film 62 made of one of gold, silver, copper and nickel is formed at the bonding interface with the wire bonding layer WBL.

As a modified example of the present embodiment, there may be cases where a wire bonding layer WBL is directly sintered on a source electrode pad SE. However, from the viewpoint of improving the bonding reliability of the path that electrically connects the wire bonding layer WBL and the source electrode pad SE to each other, it is preferable that a metal film 62 made of any of gold, silver, copper and nickel is adhered to the lower surface WBLb of the wire bonding layer WBL.

The metal film 61 shown in FIG. 7 can be omitted. In the example shown in FIG. 7, since a metal film 61 made of nickel is provided as an underlayer of the metal film 62, it functions as an oxidation prevention film that prevents oxidation of the portion of the source electrode pad SE exposed from the insulating film 14.

### <Details of Die Bonding Material>

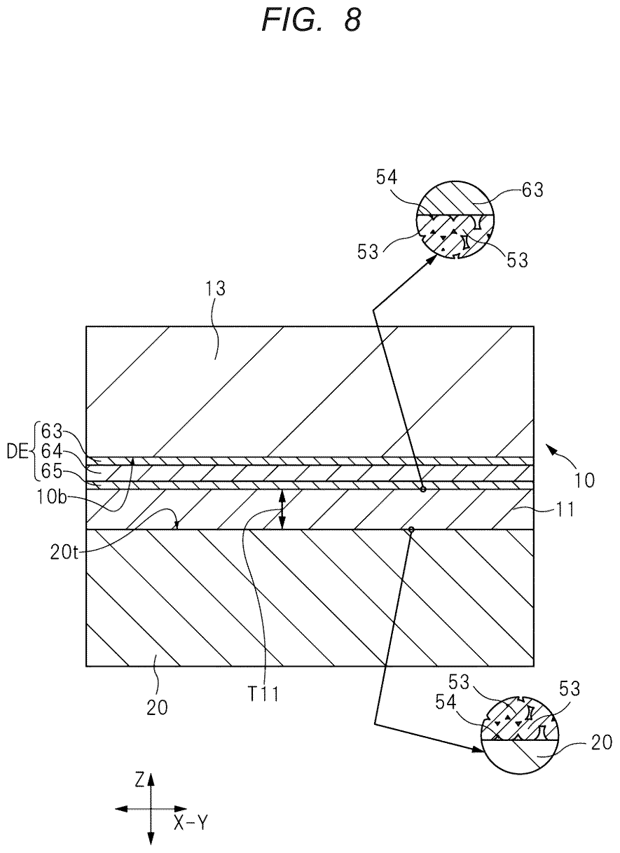

Next, the peripheral structure of the die bond material shown in FIG. 4 will be explained using FIG. 8. FIG. 8 is an enlarged cross-sectional view showing a part of each of the semiconductor chip, die bond material, and die pad shown in FIG. 4.

As shown in FIG. 8, in case of the present embodiment, the die bond material 11 consists of sintered metal. As shown in FIG. 8, the die bond material 11 is a sintered body in which multiple metal particles 53 are sintered together. Each of the multiple metal particles 53 is a fine particle with a particle size in the submicron order. Moreover, a large number of metal particles 53 can be handled as a powder. Metal particles with a particle size in the nanometer order may also be used. This allows for the sintering of multiple metal particles together at a lower temperature and under a lower load. However, when using metal particles in the nanometer order, there is a risk that the member cost (i.e., the manufacturing cost of the semiconductor device) may be higher compared to metal particles in the submicron order. Metal particles with a particle size in the micron order may also be used. This can reduce costs. However, when using metal particles in the micron order, there is a risk that reactivity (sinterability) may decrease compared to metal particles in the submicron order. Moreover, the die bond material 11, being a sintered body, is a porous body that includes voids 54 between the sintered metal particles 53. In the case where the die bond material 11 consists of sintered metal as shown in FIG. 8, the wire bonding layer WBL (refer to FIG. 7) can be sintered together with the die bond material 11 in the sintering process.

In case of the present embodiment, the die bond material 11 consists of the same sintered copper as the wire bonding layer WBL shown in FIG. 7. In other words, each of the multiple metal particles 53 shown in FIG. 8 is a copper particle.

As a modified example of the present embodiment, there may be cases where the wire bonding layer WBL and the die bond material 11 are made of different materials from each other. For instance, one of the wire bonding layers WBL and the die bond material 11 may be made of sintered copper while the other is made of sintered silver. However, when the sintering process is performed in a batch, the sintering process temperature is treated at the same temperature. Therefore, from the perspective of aligning the sintering state of the wire bonding layer WBL and the die bond material 11, it is preferable that the wire bonding layer WBL and the die bond material 11 are made of the same material.

Furthermore, as another modified example of the present embodiment, the die bond material 11 may be made of, for example, solder or conductive resin. In this modified example, since the die bond material 11 is hardened first, and then the wire bonding layer WBL is sintered, the sintering temperature of the wire bonding layer WBL needs to be such that the already hardened die bond material 11 does not re-melt or suffer thermal damage.

Therefore, in terms of reducing the constraints on the sintering temperature, it is preferable that each of the wire bonding layer WBL and the die bond material 11 is made of a sintered metal, and it is particularly preferable that they are made of the same material.

As shown in FIG. 8, a metal film 65 made of one of gold, silver, copper and nickel is formed at the portion, which is in contact with the die bond material 11, of the drain electrode pad DE. In the example shown in FIG. 8, the drain electrode pad DE is a laminated film of metal film 63, metal film 64, and metal film 65, in order from the side of the semiconductor substrate 13.

The metal film 63 is a titanium film made of titanium, which has good adhesion to the semiconductor substrate 13 made of silicon. The metal film 64 is, for example, a nickel film made of nickel. Moreover, the metal film 65 is, for example, a silver film made of silver.

If the die bond material 11 is made of sintered silver, it is preferable that the metal film 65 is made of one of gold, silver and copper. On the other hand, if the die bond material 11 is made of sintered silver, it is preferable that the metal film 65 is made of one of gold, silver, copper and nickel.

By placing a metal film 65 made of one of the above metals on the portion of the drain electrode pad DE that contacts the die bond material 11 made of a sintered metal, it is possible to easily sinter the die bond material 11 and the drain electrode pad DE.

However, as mentioned above, if the die bond material 11 is made of solder or conductive resin, the metal film 65 is preferably made of gold or silver. When solder is bonded to a metal film 65 made of gold or silver, a good connection state of the bonding interface can be obtained.

Furthermore, if the die bond material 11 is made of conductive resin, electrical connection reliability can be improved by adhering multiple metal particles (for example, silver particles) contained in conductive particles to a metal film 65 made of gold or silver. In addition, if the die bond material 11 is a conductive resin, the adhesive strength between the drain electrode pad DE and the die bond material 11 is determined by the adhesive strength between the resin contained in the conductive resin and the drain electrode pad DE.

In the example shown in FIG. 8, the die bond material 11 is directly bonded on the upper surface 20t of the die pad 20 made of copper or a copper alloy. However, as a modified example to FIG. 8, on the upper surface 20t of the die pad 20, a metal film made of, for example, silver (not shown) may be arranged, and the die bond material 11 may be bonded to this metal film made of silver. Particularly, when the die bond material 11 is made of sintered silver, solder, or conductive resin, it is preferable to interpose a metal film made of gold or silver between the die bond material 11 and the die pad 20.

The wire bonding layer WBL and the die bond material 11 each comprise, for example, sintered metal as mentioned above, but their thicknesses are different from each other. That is, the thickness TWBL of the wire bonding layer WBL shown in FIG. 7 is larger than the thickness T11 of the die bond material 11.

The wire bonding layer WBL, as described above, is provided to prevent or suppress damage to the source electrode pad SE when bonding the wire 12 shown in FIG. 7. On the other hand, the die bond material 11 shown in FIG. 8, as long as it fulfills the function of fixing the semiconductor chip 10 on the die pad 20 and the function of electrically connecting the semiconductor chip 10 and the die pad 20, its thickness T11 may be thin. Therefore, it is preferable that the thickness TWBL of the wire bonding layer WBL is larger than the thickness T11 of the die bond material 11.

For instance, the thickness TWBL of the wire bonding layer WBL is approximately 60 μm. Furthermore, the thickness T11 of the die bond material 11 shown in FIG. 8 (in other words, the separation distance between the lower surface 10b of the semiconductor chip 10 and the upper surface 20t of the die pad 20) is, for example, about 30 μm.

As described above, as a modified example of the present embodiment, in the case where the die bond material shown in FIG. 4 is solder or conductive resin, it is not necessary to increase the thickness of the die bond material 11, and it is preferable that the thickness TWBL of the wire bonding layer WBL is larger than the thickness T11 of the die bond material 11.

### <Manufacturing Method of Semiconductor Device>

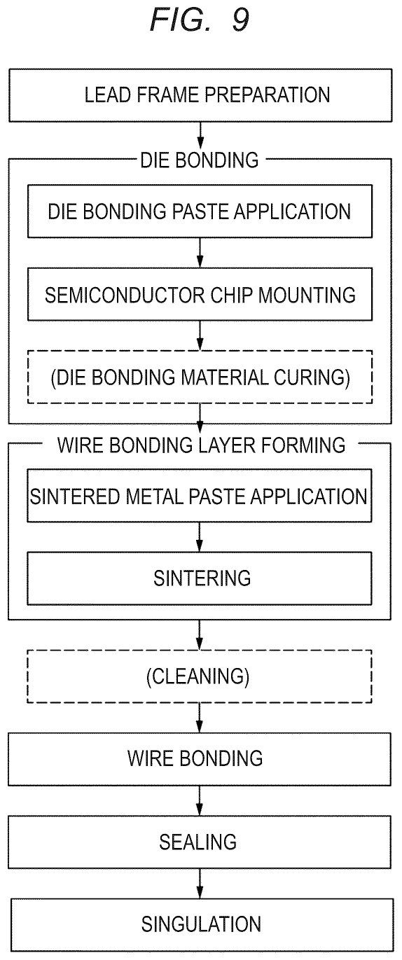

Next, a method of manufacturing the semiconductor device shown in FIGS. 1 to 4 will be explained. FIG. 9 is a flowchart showing an example of the manufacturing process of the semiconductor device according to the present embodiment. In the example shown in FIG. 9, the manufacturing method of the semiconductor device of the present embodiment includes a lead frame preparation process, semiconductor chip mounting process, wire bonding process, encapsulation process, solder film formation process, and singulation process.

### <Lead Frame Preparation Step>

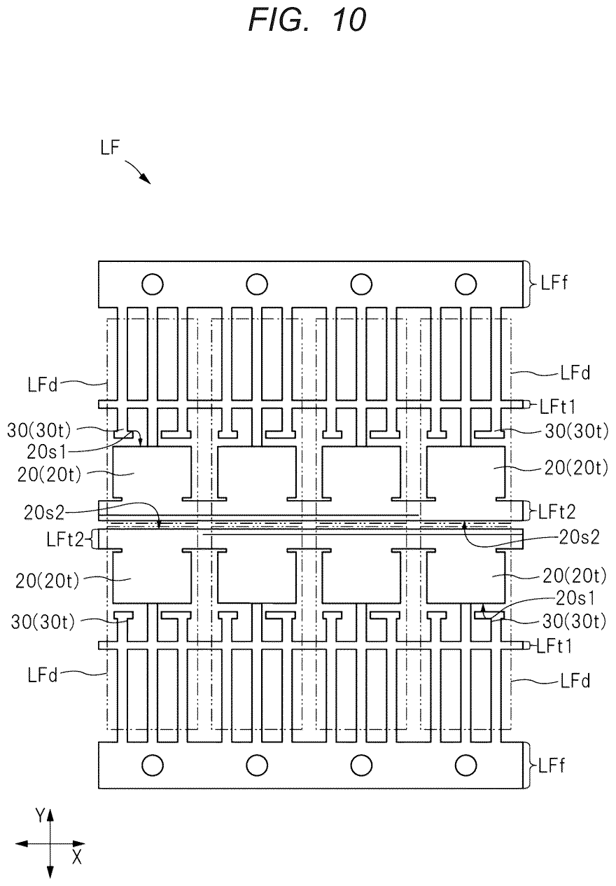

First, in the lead frame preparation step shown in FIG. 9, a lead frame LF shown in FIG. 10 is prepared. FIG. 10 is an enlarged plan view showing a part of the lead frame prepared in the lead frame preparation step shown in FIG. 9.

As shown in FIG. 10, the lead frame LF prepared in this step includes multiple device formation sections LFd connected to the frame section (frame part) LFf. FIG. 10 shows eight device formation sections LFd. Each of the multiple device formation sections LFd corresponds to one semiconductor device PKG1 shown in FIG. 1. The lead frame LF is a so-called multi-unit substrate with multiple device formation sections LFd arranged in a matrix. Thus, using a lead frame LF including the multiple device formation sections LFd allows for the batch manufacturing of multiple semiconductor devices PKG1 (refer to FIG. 1), thereby improving manufacturing efficiency. Note that FIG. 10 shows an example where two rows of multiple device formation sections LFd are arranged along the X direction, but there are various modified examples of the arrangement of the device formation sections LFd. For example, a single row or more than three rows may be used.

The lead frame LF is mainly made of copper (Cu). Each of the multiple device formation sections LFd is connected to the frame section LFf. The frame section LFf serves as a support section that supports each component formed within the device formation sections LFd until the singulation step shown in FIG. 9.

Moreover, a die pad 20 and a plurality of leads 30 are formed in the device formation sections LFd as shown in FIG. 3. The die pad 20 is connected to the frame section LFf via one of the plurality of leads 30 and is supported by the frame section LFf. Also, each of the plurality of leads 30 is connected to and supported by the frame section LFf.

Focusing on one of the multiple device formation sections LFd, this step can be expressed as a die pad preparation step, namely, a step for preparing a die pad having an upper surface 20t.

Furthermore, each of the plurality of leads 30 is interconnected via a tie bar LFt1. In the example shown in FIG. 10, each of the plurality of die pads 20 is interconnected via a tie bar LFt2. As shown in FIG. 10, the tie bar LFt2 is positioned on the opposite side of the plurality of leads 30 via the die pad 20 in the device forming section LFd and includes a side 20s2 opposite to the side 20s1 facing the plurality of leads 30.

A groove T21, as shown in FIGS. 7 and 9, is formed in the die pad 20. The groove T21 is formed by press processing using a mold during the lead frame preparation process.

Among the plurality of leads 30, the leads 30 corresponding to the source lead 30S and the gate lead 30G shown in FIG. 3 each has a wire bonding area 30W. In the lead frame preparation step, a metal film 33 is formed on the wire bonding area 30W so as to cover the upper surface 30t. The metal film 33 is made of silver and can be formed, for example, by plating.

As mentioned above, a metal film made of, for example, silver may be formed on the upper surface 20t of the die pad 20. In this case, for example, the metal film 33 can be formed simultaneously with the formation of the metal film on the die pad 20.

### <Die Bonding Step>

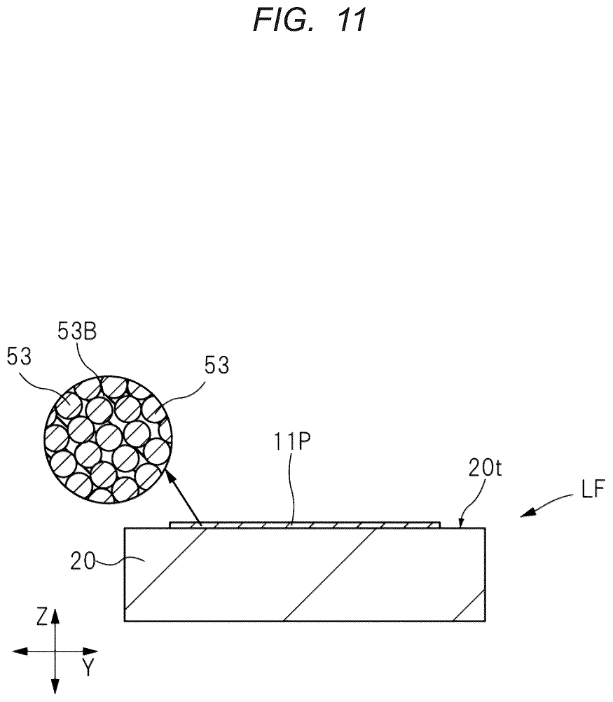

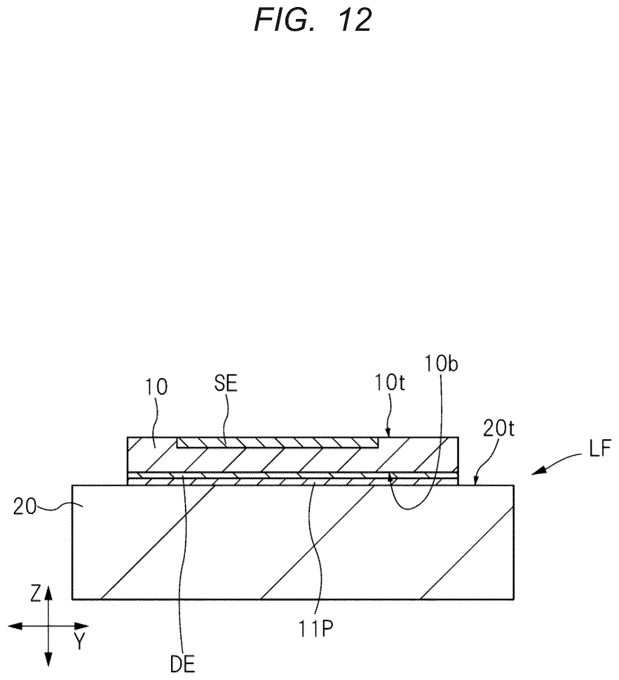

Next, in the die bonding step shown in FIG. 9, a semiconductor chip 10 is mounted on the die pad 20 as shown in FIG. 3. As shown in FIG. 9, the die bonding step includes a die bonding paste application step and a semiconductor chip mounting step. FIG. 11 is an enlarged cross-sectional view showing the state where the die bonding paste is applied onto the die pad in the die bond paste application step of FIG. 9. FIG. 12 is an enlarged cross-sectional view showing the state where the semiconductor chip is mounted on the die bonding paste shown in FIG. 11.

In the die bond paste application step, as shown in FIG. 11, for example, a die bonding paste material (die bonding paste) 11P is applied onto the upper surface 20t of the die pad 20. The die bonding paste material 11P has a binder 53B and multiple metal particles 53 mixed in the binder 53B.

In the present embodiment, each of the multiple metal particles 53 is, for example, a copper particle. As a modified example, each of the multiple metal particles 53 may be a silver particle. The binder 53B is an organic solvent that holds each of the multiple metal particles 53 by its adhesiveness. The paste material 11P has a paste-like property as a whole and can be formed on the die pad 20 as shown in FIG. 11.

Although not shown in FIG. 9, after the die bonding paste application step and before the semiconductor chip mounting step, a drying step may be performed to dry the paste material 11P shown in FIG. 11. In the drying step, for example, a heat treatment is performed for about 10 minutes at 120 degrees Celsius in a heating furnace where the lead frame LF is placed. If this drying step is performed, a part of the binder 53B evaporates, increasing the density of the multiple metal particles 53, thereby making it easier to sinter the multiple metal particles 53 (see FIG. 11) together in the sintering treatment step shown in FIG. 9.

In the semiconductor chip mounting step, as shown in FIG. 12, a semiconductor chip 10 having a source electrode pad SE is mounted on a paste material 11P for die bonding. In this step, the lower surface 10b of the semiconductor chip 10 is pressed against the paste material 11P. At this time, the lower surface 10b of the semiconductor chip 10 is adhered to the paste material 11P due to the adhesive force of the binder 53B contained in the paste material 11P.

As in the present embodiment, when the die bonding material 11 shown in FIG. 4 is made of sintered metal, in this step, the sintering is not performed, and the paste material 11P is sintered in the sintering treatment step shown in FIG. 9.

On the other hand, as a modified example to the present embodiment, when the die bonding material 11 shown in FIG. 4 is made of solder or conductive resin, the die bonding step includes a curing step of the die bonding material, as indicated by the dotted line in FIG. 9. In the die bond material step, the paste (solder paste or conductive resin paste), which is the raw material of the die bonding material, is cured.

In case of curing the solder paste, in the die bonding material curing step, the solder paste is heated to above the melting point of the solder paste contained therein and then cooled (referred to as reflow processing). On the other hand, in case of curing the conductive resin paste, in the die bonding material curing step, the conductive resin paste is heated to above the curing temperature of the thermosetting resin contained therein and maintained at a high temperature to cure the thermosetting resin (referred to as cure bake processing). In these modified examples, upon completion of the die bonding step, the semiconductor chip 10 is fixed on the die pad 20 via the die bonding material 11.

### <Wire Bonding Layer Forming Step>

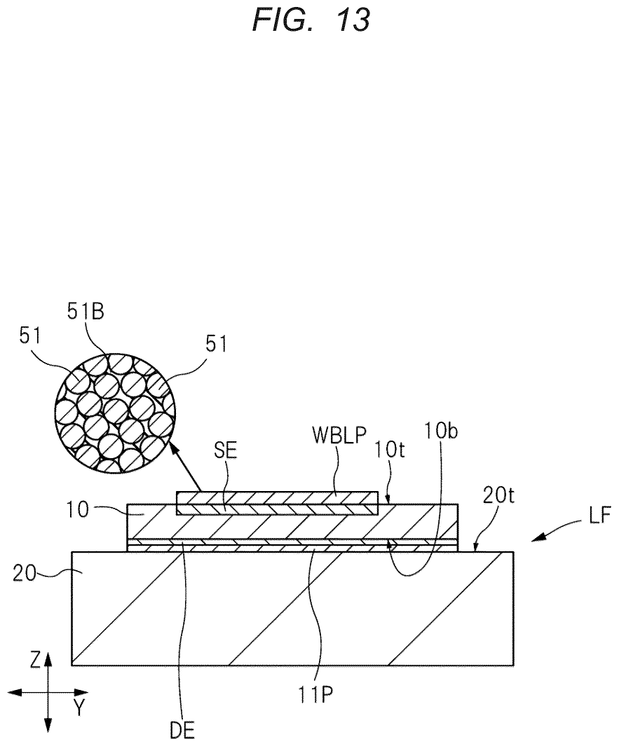

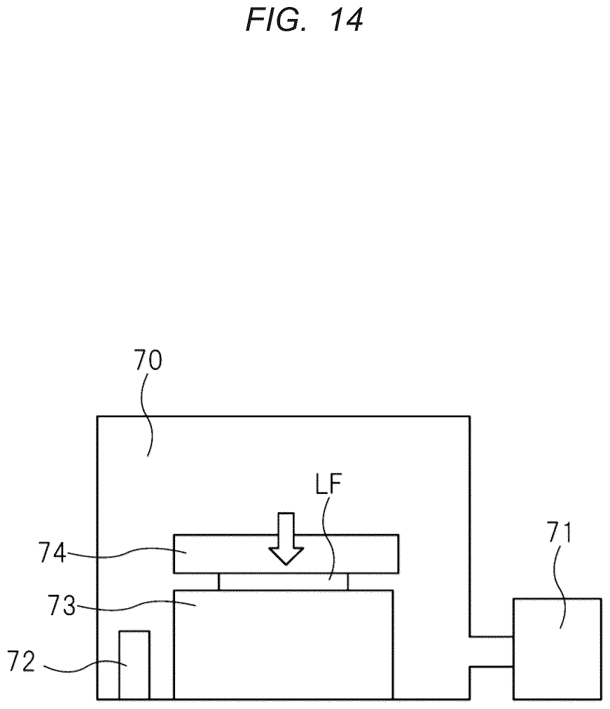

Next, the wire bonding layer formation step shown in FIG. 9 includes a sintering metal paste application step and a sintering treatment step. FIG. 13 is an enlarged cross-sectional view showing the state where the paste for sintering metal is applied onto the die pad in the sintering metal paste application process of FIG. 9. FIG. 14 is an explanatory diagram schematically showing the state of heating the lead frame in a vacuum furnace in the sintering process shown in FIG. 9. In the sintering metal paste application step, for example, as shown in FIG. 13, a paste material (paste material for sintering metal) WBLP, which is a raw material for the wire bonding layer, is applied onto the source electrode pad SE of the semiconductor chip 10. The paste material for the wire bonding layer 11P contains a binder 51B and multiple metal particles 51 mixed in the binder 51B.

In the present embodiment, each of the multiple metal particles 51 is, for example, a copper particle. As a modified example, there may be cases where each of the multiple metal particles 51 is a silver particle. The binder 51B is an organic solvent that holds each of the plurality of metal particles 51 by its adhesiveness. The paste material WBLP has a paste-like property as a whole and can be thickly formed on the source electrode pad SE as shown in FIG. 13.

In the present embodiment, the thickness of the paste material WBLP applied onto the source electrode pad SE is, for example, 60 μm or more. Thus, in the method of applying the paste material WBLP, for example, it is possible to make the thickness TWBL of the wire bonding layer WBL shown in FIG. 7 thicker compared to the method of forming a metal film by plating.

Various methods can be used for applying the paste material WBLP. For example, as a method of applying the paste material WBLP, a method can be exemplified where the paste material WBLP is directly dispensed on the source electrode pad SE using a dispenser not shown in the figures, and then formed. Or a method can be exemplified where the paste material WBLP is directly applied onto the source electrode pad SE while being formed into a plate shape using a printing coating device not shown in the figures. Or a method can be exemplified where the paste material WBLP, which is pre-formed into a plate shape as shown in FIG. 13, is arranged on the source electrode pad SE.

Although not shown in FIG. 9, after the sintering paste application step and before the sintering treatment step, a drying step may be performed where the applied paste material WBLP (refer to FIG. 13) is dried. In the drying step, for example, a heating treatment is performed for about 10 minutes at 120 degrees Celsius with the lead frame LF placed in a heating furnace not shown in the figures. When this drying step is performed, a part of the binder 51B evaporates, increasing the density of the multiple metal particles 51, thereby making it easier to sinter the multiple metal particles 51 (refer to FIG. 13) together in the sintering treatment step shown in FIG. 9.

Next, in the sintering treatment step shown in FIG. 9, as shown in FIG. 14, for example, a lead frame LF is placed in a vacuum furnace 70 and heated under a reduced pressure atmosphere. In the example shown in FIG. 14, the vacuum furnace 70 is equipped with a sealed space connected to a vacuum pump 71, and by discharging the gas in the sealed space to the outside with the vacuum pump 71, a reduced pressure state can be created. Furthermore, a heater 72 is arranged inside the vacuum furnace 70, capable of heating the temperature within the sealed space. It should be noted that there are various modified examples of the method for heating the lead frame LF placed inside the vacuum furnace 70. For instance, in the example shown in FIG. 14, heaters may be incorporated into both the stage 73 and the pressing jig 74.

The reason for performing this step under a reduced pressure atmosphere is to inhibit the growth of the oxide film formed on the surface of the sintered metal due to the sintering process. Especially, in case of sintered copper, since an oxide film is more likely to form compared to sintered silver, it is preferable to perform the sintering treatment step under a reduced pressure atmosphere.

As a modified example of the present embodiment, there is a method of performing the sintering treatment step under an inert gas atmosphere such as nitrogen gas. Alternatively, as another modified example, there is a method of performing the sintering treatment step under a reducing atmosphere using, for example, formic acid. From the perspective of preventing the growth of the oxide film formed on the sintered metal, the modified examples performed under an inert gas atmosphere or under a reducing atmosphere are also effective.

However, when performing the sintering treatment step under a reduced pressure atmosphere, an effect of promoting the evaporation of the binder 51B shown in FIG. 13 can be obtained. In this respect, it is particularly preferable to perform the sintering treatment step under a reduced pressure atmosphere.

In the sintering treatment step, as schematically shown with white arrows in FIG. 14, the lead frame LF is heated while being clamped between the stage 73 and the pressing jig 74, with a pressing force applied. The heating temperature and time vary depending on the type of metal used, but for example, in case of forming sintered copper, it is heated at 260 degrees Celsius for 5 minutes with a pressing force of 10 MPa applied.

In this step, from the perspective of making it easier to control the sintered state of the die bond material 11 and the wire bonding layer WBL, as already explained, it is particularly preferable that the die bond material 11 and the wire bonding layer WBL are made of the same sintered metal.

The multiple metal particles 53 shown in FIG. 11 are sintered by this step and bond together. At this time, as shown in FIG. 8, a part of the multiple metal particles 53 is sintered to the die pad 20, and another part is sintered to the drain electrode pad DE.

Similarly, the multiple metal particles 51 shown in FIG. 13 are sintered by this step and bond together. At this time, as shown in FIG. 7, part of the multiple metal particles 51 is sintered to the source electrode pad SE (specifically, to the metal film 62 formed on the source electrode pad SE).

It should be noted that, although FIG. 13 shows an example of the state in which the paste material WBLP is applied onto the source electrode pad SE, in case of forming the wire bonding layer WBLG on the gate electrode pad GE shown in FIG. 3, in this step, the paste material WBLP (refer to FIG. 13) that becomes the raw material for the wire bonding layer WBLG is applied onto the gate electrode pad GE.

### <Cleaning Step>

Next, prior to the wire bonding step shown in FIG. 9, there may be a step of cleaning the wire bonding layer formed in the wire bonding layer formation step shown in FIG. 9, as a cleaning treatment step. In the cleaning step, the wire bonding layer is cleaned using a cleaning material, thereby removing the oxide film formed on the surface of the wire bonding layer and thus exposing the unoxidized metal on the surface. The cleaning material used in the present embodiment is closer to neutral than acidic. Therefore, it is possible to reduce damage to the wire bonding layer. On the other hand, if one wishes to ensure the removal of the oxide film, an acidic cleaning material may be used.

The acid cleaning step includes the step of removing the oxide film with an acidic solution such as sulfuric acid, the step of washing away the acidic solution with water, and the step of drying to remove residual moisture.

If the oxide film can be removed by the acid cleaning step, the sintering step shown in FIG. 9 can be carried out in an atmospheric environment. Furthermore, by conducting the sintering step under reduced pressure, in an inert gas atmosphere, or in a reducing atmosphere, if the thickness of the oxide film formed on the surface of the wire bonding layer between the sintering step and the wire bonding step is negligibly thin, the acid cleaning step can be omitted.

However, as mentioned above, since the sintered metal is a porous body, there are cases where the cleaning liquid does not completely cover the surface of the metal. Also, there may be a long-time lag between the wire bonding layer forming step and the wire bonding step. In such cases, there is a risk of growth of the oxide film on the surface of the sintered metal. Therefore, from the perspective of joining the wire 12 and the wire bonding layer WBL in a good connection state as shown in FIG. 7, it is particularly preferable to perform the sintering step under reduced pressure, in an inert gas atmosphere or in a reducing atmosphere, and to carry out the acid cleaning step prior to the wire bonding step.

### <Wire Bonding Step>

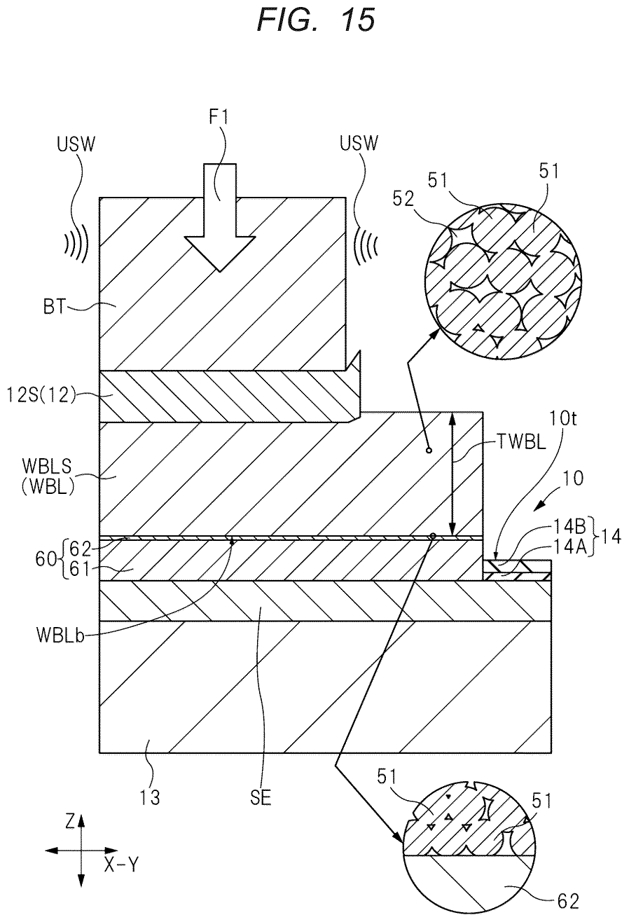

Next, in the wire bonding step shown in FIG. 9, as shown in FIG. 3, the plurality of electrode pads (gate electrode pad GE and source electrode pad SE) of the semiconductor chip 10 and the plurality of leads 30 are electrically connected with each other via a wire (metal wire) 12. FIG. 15 is an enlarged cross-sectional view schematically showing a state where a load and an ultrasonic wave are applied to the wire through a bonding tool in the wire bonding step shown in FIG. 9.

In this step, the gate electrode pad GE of the semiconductor chip 10 and the lead 30G are electrically connected with each other via the wire 12G (and the wire bonding layer WBLG). Furthermore, in this step, the source electrode pad SE of the semiconductor chip 10 and the lead 30S are electrically connected with each other via the wire 12S and the wire bonding layer WBLS.

Various modified examples can be applied to the method of connecting the wire 12. A wedge bonding method using a bonding tool called a wedge tool can be exemplified.

In the present embodiment, a metal film 33 made of silver is formed in the wire bonding area 30W (refer to FIG. 4). One end of the wire 12 is bonded to one of the gate electrode pad GE and the source electrode pad SE, and the other end of the wire 12 is bonded to the metal film 33 formed in the wire bonding area 30W.

In the present embodiment, in the wire bonding step, as shown in FIG. 15, a wire 12 made of metal, which is a different type from the source electrode pad SE, is bonded to the wire bonding layer WBL. As an example, mentioned above, the source electrode pad SE is mainly made of aluminum, and the wire 12S is made of copper.

In the wire bonding step, to ensure the wire 12 and the wire bonding layer WBL are securely bonded, as schematically shown in FIG. 15, the wire 12 and the wire bonding layer WBL are bonded in a state where a ultrasonic wave USW and a load F1 are applied to the wire 12. Furthermore, in the wire bonding step, to ensure the wire 12 and the wire bonding layer WBL are securely bonded, the wire 12 is bonded to the wire bonding layer WBL in a heated state.

At this time, when the wire 12 is directly bonded to the source electrode pad SE shown in FIG. 15, or bonded to the metal film 60 shown in FIG. 15, the force transmitted to the source electrode pad SE through the hard wire 12 may cause damage to the source electrode pad SE.

On the other hand, in the present embodiment, as already explained, the wire bonding layer WBL, which is a sintered metal, can be made thicker than the method of forming a metal film by plating, since the paste-like raw material is molded. Therefore, the external force when bonding the wire 12 is less likely to be transmitted to the source electrode pad SE.

Furthermore, the wire bonding layer WBL made of sintered metal is a porous body. Therefore, the external force when bonding the wire 12 is mitigated by the voids 52 of the wire bonding layer WBL, making it difficult to transmit to the source electrode pad SE. In case of the present embodiment, the wire bonding layer WBL made of sintered metal is provided, and the wire 12 is bonded to the wire bonding layer WBL. As a result, it is possible to prevent or suppress damage to the source electrode pad SE when bonding the wire 12. By suppressing damage to the source electrode pad SE, it is possible to improve the electrical connection reliability of the path that electrically connects the wire 12 and the source electrode pad SE.

In this section, the step of electrically connecting the source electrode pad SE and the wire 12S is described as an example, but the step of electrically connecting the gate electrode pad GE and the wire 12G shown in FIG. 3 is similar.

Moreover, in case of the present embodiment, no cleaning step is performed after the wire bonding step. However, as a modified example, an acid cleaning step described above may be performed after the wire bonding step. Since the wire bonding step is performed in a heated state, an oxide film may form on the wire bonding layer WBL during the wire bonding step, and this oxide film may grow. If an acid cleaning step is performed after the wire bonding step, it is possible to remove this oxide film, thereby suppressing an increase in the resistance value of the wire bonding layer WBL.

### <Sealing Step>

Next, in the sealing step shown in FIG. 9, the semiconductor chip 10 shown in FIG. 3, a part of the die pad 20, a part of each of the plurality of leads 30 (the inner lead portion 30M shown in FIG. 4), the wire bonding layer WBL, and the plurality of wires 12 are sealed with an insulating resin to form the sealing body 40 shown in FIG. 4.

In this step, for example, a molding die including an upper mold (first mold) and a lower mold (second mold) is used to form the encapsulated body 40 by a so-called transfer mold method. The die pad 20 and the inner lead portions 30M of the multiple leads 30 (refer to FIG. 4) of the device forming part LFd shown in FIG. 10 are positioned within the cavity of the molding die by placing the lead frame LF. Then, the lead frame LF is clamped between the upper and lower molds. In this state, when a softened (plasticized) thermosetting resin (insulating resin) is pressed into the cavity of the molding die, the insulating resin is molded following the shape of the cavity.

At this time, a part of the upper surface 20t of the die pad 20, which is contiguous to the edge 20s2, and the lower surface 20b of the die pad 20 are in close contact with the molding die. Therefore, as shown in FIG. 4, after this step, a part of the upper surface 20t and the lower surface 20b of the die pad 20 are exposed from the sealing body 40.

After the sealing body 40 is formed, it is heated until a part of the thermosetting resin contained in the sealing body 40 hardens (referred to as provisional hardening). Once it becomes possible to remove the lead frame LF from the molding die due to this provisional hardening, the lead frame LF is removed from the molding die. Then, it is transported to a heating furnace and further subjected to a heat treatment (cure bake). As a result, the remaining part of the thermosetting resin hardens, and the sealing body 40 is obtained.

Moreover, although the sealing body 40 is mainly composed of an insulating resin, by mixing filler particles such as silica (silicon dioxide; SiO2) particles into the thermosetting resin, it is possible to improve the function of the sealing body 40 (for example, resistance to warping deformation).

### <Solder Film Forming Step>

Although not shown in FIG. 9, when forming the metal film 32 shown in FIG. 4, as a solder film forming step, the lead frame LF is dipped in a plating solution not shown, and a metal film (the metal film 32 shown in FIG. 4) is formed on the surface of the metal part (outer part) exposed from the sealing body 40. The metal film 22 formed on the lower surface 20b of the die pad 20 shown in FIG. 4, for example, is pre-formed in the lead frame preparation step. As a method for forming the metal film 22, plating can be exemplified, for example.

In this step, for example, by the solder dip method, a metal film 32 made of solder (refer to FIG. 4) is formed on each of the exposed parts of the multiple leads 30 (outer lead part 30X shown in FIG. 4). Although not shown, the solder dip method involves placing the lead frame LF shown in FIG. 10 in a solder bath containing molten solder. At this time, only the parts of the plurality of leads 30 are selectively dipped in the molten solder, and most of the sealing body 40 is not dipped in the molten solder. This allows for the formation of a metal film 32 made of solder (refer to FIG. 4) on each of the plurality of leads 30.

### <Singulation Step>

Next, the singulation step shown in FIG. 9 includes a lead cut process for cutting the tip parts of the plurality of leads 30 shown in FIG. 10, and a tie bar cutting step for cutting the tie bar LFt1 shown in FIG. 10. In case of the present embodiment, the singulation step includes a lead forming step for bending the outer lead part 30X of the lead 30 as shown in FIG. 4. For example, in the present embodiment, the singulation step is carried out in the order of the lead cutting step, the lead forming step, and the tie bar cutting step.

In the lead cutting step, the plurality of leads 30 is separated from the frame part LFf, thereby separating each of the plurality of leads 30. In this step, the tip parts of the plurality of leads 30 are cut by press processing (cutting processing) using a punch and die not shown. The newly formed tip surfaces by this step are not covered with the metal film 32.

In the lead forming step, the outer lead portion 30X of the lead 30 is formed by press processing using a punch and die, not shown in the figures. In the example shown in FIG. 4, the outer lead portion 30X is formed in a gull-wing shape.

In the tie bar cutting step, the tie bar LFt1 shown in FIG. 10 is cut. Furthermore, in the tie bar cutting step, the tie bar LFt2 is cut, and the plurality of die pads 20 connected via the tie bar LFt2 are each divided. After this step, the plurality of leads 30 are connected via the frame part LFf. Also, the plurality of die pads 20 become connected via the drain lead 30D, which functions as a suspension lead (see FIG. 3), and the frame part LFf.

For cutting the tie bars LFt1 and LFt2, press processing (cutting processing) using a punch and die, not shown in the figures, can be used. This step is performed after the solder film forming step, so the newly formed sides by this step are not covered with the metal film 32. Through this step, the device forming part LFd shown in FIG. 10 is individualized, and the semiconductor device shown in FIG. 1 is obtained.

Through the above processes, the semiconductor device PKG1 shown in FIGS. 1 to 4 is obtained. Thereafter, tests such as electrical testing and visual inspection are conducted as necessary, and those deemed to be non-defective are transported to the next step, such as packaging of the semiconductor device.

Although the invention made by the present inventor has been specifically described based on the embodiment, the present invention is not limited to the above embodiment, and it is needless to say that various modifications can be made without departing from the gist thereof.

What is claimed is:

1. A semiconductor device comprising:
a die pad;
a lead spaced apart from said die pad;
a semiconductor chip mounted on said die pad via a die bonding material, said semiconductor chip including a first electrode pad;
a wire electrically connected with each of said lead and said first electrode pad of said semiconductor chip; and
a sealing body sealing said semiconductor chip, said die bonding material and said wire,
wherein said first electrode pad and said wire are made of different types of metals to each other,
wherein a wire bonding layer made of sintered metal is interposed between said first electrode pad and said wire, and
wherein said wire is electrically connected with said first electrode pad via said wire bonding layer.

2. The semiconductor device according to claim 1,
wherein said wire is made of copper, and
wherein said first electrode pad is mainly made of aluminum.

3. The semiconductor device according to claim 2, wherein said wire bonding layer is made of sintered copper.

4. The semiconductor device according to claim 3,
wherein a first metal film is interposed between said wire bonding layer and said first electrode pad, and
wherein a metal film made of one of gold, silver, copper and nickel is formed at a portion, which is in contact with said wire bonding layer, of said first metal film.

5. The semiconductor device according to claim 1, wherein said die bonding material is made of sintered metal.

6. The semiconductor device according to claim 5,
wherein said wire is made of copper,
wherein said first electrode pad is mainly made of aluminum, and
wherein each of said wire bonding layer and said die bonding material is made of sintered copper.

7. The semiconductor device according to claim 5,
wherein said semiconductor chip has:
a first surface facing said die pad,
a second surface opposite said first surface, and
a second electrode pad formed on said second surface,
wherein a first metal film is interposed between said wire bonding layer and said first electrode pad,
wherein a metal film made of one of gold, silver, copper and nickel is formed at a portion, which is in contact with said wire bonding layer, of said first metal film, and
wherein a metal film made of one of gold, silver, copper and nickel is formed at a portion, which is in contact with said die bonding material, of said second electrode pad.

8. The semiconductor device according to claim 5, wherein a thickness of said wire bonding layer is larger than a thickness of said die bonding material.

9. The semiconductor device according to claim 1,
wherein said semiconductor chip includes a power transistor made of one of power MOSFET and IGBT, and
wherein said first electrode pad is electrically connected with a source of said power MOSFET or an emitter of said IGBT.

10. A method of manufacturing a semiconductor device, comprising steps of:
(a) preparing a lead frame including a die pad;
(b) applying a first paste material onto said die pad;
(c) mounting a semiconductor chip on said first paste material, said semiconductor chip having a first electrode pad;
(d) arranging a second paste material containing multiple metal particles on said first electrode pad of said semiconductor chip;
(e) sintering said multiple metal particles contained in said second paste material by heating, thereby forming a wire bonding layer; and
(f) bonding a wire to said wire bonding layer, said wire being made of metal which is a different type from said first electrode pad.

11. The method according to claim 10,
wherein said first paste material is made of a material which is the same as a material of said second paste material, and
wherein in said step of (e), by heating said first paste material, multiple metal particles contained in said first paste material are sintered, thereby forming a die bonding material fixing said semiconductor chip on said die pad.

12. The method according to claim 11,
wherein each of said multiple metal particles is a copper particle, and
wherein after said step of (e) and before said (f) step, said wire bonding layer is cleaned by using an acidic cleaning material.

13. The method according to claim 10, wherein in said step of (f), said wire and said wire bonding layer are bonded to each other under a condition that an ultrasonic wave and a load are applied to said wire.

14. The method according to claim 10,
wherein said wire is made of copper, and
wherein said first electrode pad is mainly made of aluminum.

15. The method according to claim 13, wherein each of said multiple metal particles is a copper.

16. The method according to claim 10, wherein the step of (e) is performed under one of a reduced pressure treatment atmosphere, an inert gas atmosphere, and a reducing atmosphere.
